(19) United States
(12) Patent Application Publication
(10) Pub. No.: US 2006/0012363 A1
(43) Pub. Date: Jan. 19, 2006

(54) Method of production of magnetic disk device and apparatus for inspection of magnetic disk device

(75) Inventor: Kissei Matsumoto, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Sony Corporation, Tokyo (JP)

(21) Appl. No.: 11/178,389

(22) Filed: Jul. 12, 2005

(30) Foreign Application Priority Data
Jul. 13, 2004 (JP) P2004-205505

(51) Int. Cl. G01R 33/12

(52) U.S. Cl. 324/212

(57) ABSTRACT

A method of producing a magnetic disk device having a disk drive part including a magnetic disk and a drive unit for driving the magnetic disk and a control part for controlling the drive unit to control access to the magnetic disk and write a servo signal on the magnetic disk, including a first step of inspecting magnetic conversion characteristics of the drive unit and a second step of connecting the disk drive part and the control part when it is judged by the inspection of the first step that the magnetic conversion characteristics of the drive unit are proper.

### CROSS REFERENCE TO RELATED APPLICATIONS

The present invention contains subject matter related to Japanese Patent Application No. 2004-205505 filed in the Japan Patent Office on Jul. 13, 2004, the entire contents of which being incorporated herein by reference.

### BACKGROUND OF THE INVENTION

1. Field of the Invention

The present invention relates to a method for producing for example a self-servo type magnetic disk device and an apparatus for inspection of the magnetic disk device.

2. Description of the Related Art

There is known, for example, a method for producing a hard disk drive (HDD) including a disk drive unit including a magnetic disk and a drive unit for driving that and made sealed in structure for preventing dust etc. from entering from outside and a control unit for access control to the disk drive unit.

The HDD records a servo signal for defining a magnetic head position in advance on the magnetic disk and records and reproduces data on the basis of the servo signal. As methods of writing this servo signal on the magnetic disk, the disk servo write method and the self-servo write method are known.

In the disk servo write method, the servo signal is stored in the magnetic disk in advance when assembling the disk drive unit. In this disk servo write method, it is necessary to separately provide a device for writing the servo signal on the magnetic disk. Further, it is necessary to be careful about disk eccentricity, and a high precision is required at the time of mechanical assembly.

In the self-servo write method, after assembling the disk drive unit and the control unit, the control unit controls the drive unit to store the servo signal in the magnetic disk. In the self-servo write method, in comparison with the disk servo write method, no write device other than the magnetic disk device is necessary for writing the servo signal. Further, since the self-servo write method has the control unit write the servo signal on the magnetic disk after assembly, it is possible to achieve a higher density and improve access in comparison with the disk servo write method.

Turning to the issue focused on it the present invention, in the self-servo write method, since the servo signal is written in the magnetic disk after the assembly, if the servo signal is not correctly recorded on the magnetic disk, sometimes the entire HDD has to be discarded after assembly, it suffers from the disadvantage of waste.

### SUMMARY OF THE INVENTION

It is desirable to provide a method of production of a magnetic disk device and an apparatus for inspection of a magnetic disk device able to avoid the wasteful cost when producing a magnetic disk device having a magnetic disk and a control unit for controlling access to it and having the control unit write a servo signal on the magnetic disk after assembly.

According to a first aspect of the present invention, there is provided a method of producing a magnetic disk device having a disk drive part including a magnetic disk and a drive unit for driving the magnetic disk and a control part for controlling the drive unit to control access to the magnetic disk and write a servo signal in the magnetic disk, including a first step of inspecting magnetic conversion characteristics of the drive unit and a second step of connecting the disk drive part and the control part when it is judged by the inspection of the first step that the magnetic conversion characteristics of the drive unit are proper.

Preferably, the method further includes a third step of having the control part control the drive unit after the second step to write the servo signal on the magnetic disk.

The first step may include a step of writing an inspection signal in the magnetic disk by the drive unit, a step of reading the inspection signal from the magnetic disk, and a step of comparing the inspection signal written on the magnetic disk and the inspection signal read out from the magnetic disk, and in the second step, the disk drive part and the control part are connected when it is judged as a result of the comparison of the inspection signals that the magnetic conversion characteristics of the drive unit are proper.

More preferably, the inspection signal may include an inspection signal having a single frequency characteristic or the inspection signal may include an inspection signal having a predetermined modulation pattern.

More preferably, in the step of writing the inspection signal, the inspection signal is written into part of the tracks of the magnetic disk.

According to a second aspect of the present invention, there is provided an inspection apparatus for inspecting a magnetic disk device having a disk drive part including a magnetic disk and a drive unit for driving the magnetic disk and a control part for controlling the drive unit to control access to the magnetic disk and write a servo signal in the magnetic disk, including an inspecting part for inspecting the magnetic conversion characteristics of the drive unit before connecting the disk drive part and the control part.

Preferably, the inspecting part outputs a control signal for connecting the disk drive means and the control means when it is judged by the inspecting means that the magnetic conversion characteristics of the drive unit are proper.

The inspecting part may write an inspection signal in the magnetic disk by the drive unit, read out the inspection signal from the magnetic disk, then compare the inspection signal written on the magnetic disk and the inspection signal read out from the magnetic disk.

More preferably, the inspection signal may include an inspection signal having a single frequency characteristic or the inspection signal may include an inspection signal having a predetermined modulation pattern.

More preferably, the inspection part writes the inspection signal by writing the inspection signal into part of the tracks of the magnetic disk.

According to the present invention, it is possible to provide a method of production of a magnetic disk device and an apparatus for inspection of a magnetic disk device able to avoid the wasteful cost when producing a magnetic disk device having a magnetic disk and a control unit for controlling access to it and having the control unit write a servo signal on the magnetic disk after assembly.

### BRIEF DESCRIPTION OF THE DRAWINGS

These and other objects and features of the present invention will become clearer from the following description of the preferred embodiments with reference to the accompanying drawings, in which:

FIG. 1 is a view of the overall configuration of a magnetic disk device to be inspected by an inspection apparatus according to an embodiment of the present invention;

FIG. 2 is a functional block diagram of an inspection apparatus according to an embodiment of the present invention;

FIG. 3 is a flow chart for explaining the operations of the magnetic disk device and the inspection apparatus shown in FIG. 1 and FIG. 2; and

FIG. 4 is a flow chart for explaining a specific example of the operations of the inspection apparatus and a processing unit shown in FIG. 3.

### DESCRIPTION OF THE PREFERRED EMBODIMENTS

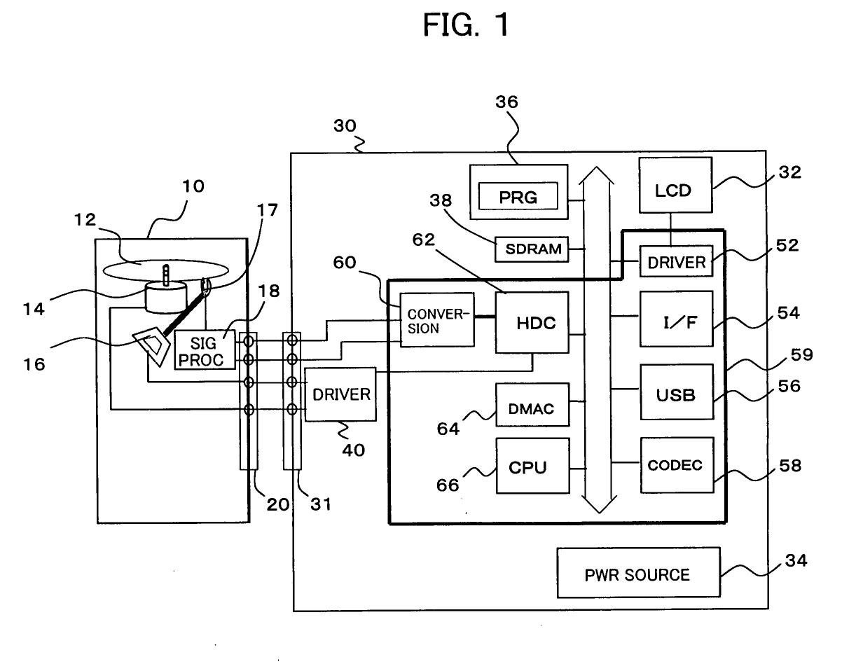

Below, preferred embodiments of the present invention will be described with reference to FIG. 1 to FIG. 4.

Magnetic Disk Device

FIG. 1 is a view of the overall configuration of a magnetic disk device 1 to be inspected by an inspection apparatus according to an embodiment of the present invention. As shown in FIG. 1, the magnetic disk device 1 has for example a hard disk assembly (HDA) 10 and a processing unit 30. The magnetic disk device 1 is for example a portable system for recording/reproducing audio data. In the magnetic disk device 1, the HDA 10 and the processing unit 30 are assembled at the time of shipping. The processing unit 30 writes the servo signal on the magnetic disk 12 of the HDA 10, that is, the self-servo write method is employed.

Below, an explanation will be given of the HDA 10 and the processing unit 30 shown in FIG. 1.

HDA 10

As shown in FIG. 1, the HDA 10 has for example a magnetic disk 12, spindle motor 14, VCM 16, head 17, signal processor 18, and interface 20. The HDA 10 has a sealed structure for preventing entry of dust from the outside.

The magnetic disk 12 has a memory region divided into a plurality of sectors in for example concentric circles. Further, the magnetic disk 12 has a plurality of tracks formed in concentric circles. The spindle motor 14 rotates the magnetic disk 12. The VCM 16 runs a current from a driver 40 of the processing unit 30 to a coil and moves the head 17 in the radial direction of the magnetic disk 12 by magnetic induction. Due to this, the head 17 is moved to the access position on the magnetic disk 12. The head 17 moves close to the recording region on the magnetic disk 12 and writes a signal, for example, an audio signal, into the sectors and tracks and reads a signal from the sectors and the tracks on the basis of the servo signal defining the position of the head 17.

The signal processor 18 amplifies the signal read out from the magnetic disk 12 by the head 17 and outputs it to the processing unit 30 via the interface 20. Further, the signal processor 18 outputs the signal to be stored input from the processing unit 30 to the head 17.

Processing Unit 30

As shown in FIG. 1, the processing unit 30 has for example an HDA interface 31, liquid crystal display (LCD) 32, power supply circuit 34, flash memory 36, synchronous DRAM (SDRAM) 38, driver 40, LCD driver 52, interface 54, universal serial bus (USB) interface 56, CODEC 58, conversion circuit 60, hard disk controller (HDC) 62, direct memory access controller (DMAC) 64, and central processing unit (CPU) 66.

In the present embodiment, the LCD driver 52, interface 54, USB interface 56, CODEC 58, conversion circuit 60, HDC 62, DMAC 64, and CPU 66 are integrally configured by for example a semiconductor integrated circuit 59.

The HDA interface 31 is connected to the interface 20 of the HDA 10 and inputs/outputs data with the HDA 10. The LCD 32 displays an image on a screen under the control of the LCD driver 52. The screen is for example an operation screen. The power supply circuit 34 supplies power to components of the processing unit 30. The flash memory 36 stores a program PRG for defining the processing of the CPU 66. The program PRG is F/W (Firm Ware). The SDRAM 38 stores the data concerning the processing of the processing unit 30. The driver 40 outputs a control signal to the spindle motor 14 and the VCM 16 of the HDA 10 under the control of the HDC 62.

The LCD driver 52 controls the display of the LCD display 32 on the basis of the control signal from the CPU 66. The interface 54 and the USB interface 56 input/output data with the outside of the processing unit 30. The CODEC 58 decodes the audio data read out from for example the HDA 10 and encodes the audio data to be stored in the HDA 10. The conversion circuit 60 performs processing such as filtering (equalization) and A/D conversion of the signal read out from the HDA 10 and outputs the audio data obtained by the processing to the HDC 62. Namely, the conversion circuit 60 functions as a so-called read channel. Further, the conversion circuit 60 performs D/A conversion of the audio data to be stored input from the HDC 62 to generate an audio signal and outputs this to the HDA 10.

The HDC 62 centrally controls the access to the HDA 10 under the control of the CPU 66. For example, the CPU 66 controls operations according to the program PRG read out from the flash memory 36.

The CPU 66 performs the processing of writing the servo signal into the HDA 10 at the time of the assembly of for example the HDA 10 and the processing unit 30 into the magnetic disk device 1. Specifically, the CPU 66 controls the spindle motor 14 serving as the drive unit, the VCM 16, head 17, signal processor 18, etc. and writes the servo signal on the magnetic disk 12 at the time of the assembly of the HDA 10 and the processing unit 30 into the magnetic disk device 1.

For example, the CPU 66 may instruct a write operation triggered by detection of the HDA 10 and the processing unit 30 being electrically connected at the time of assembly or may instruct a write operation triggered by a signal instructing a write operation from the outside.

Inspection Apparatus 70

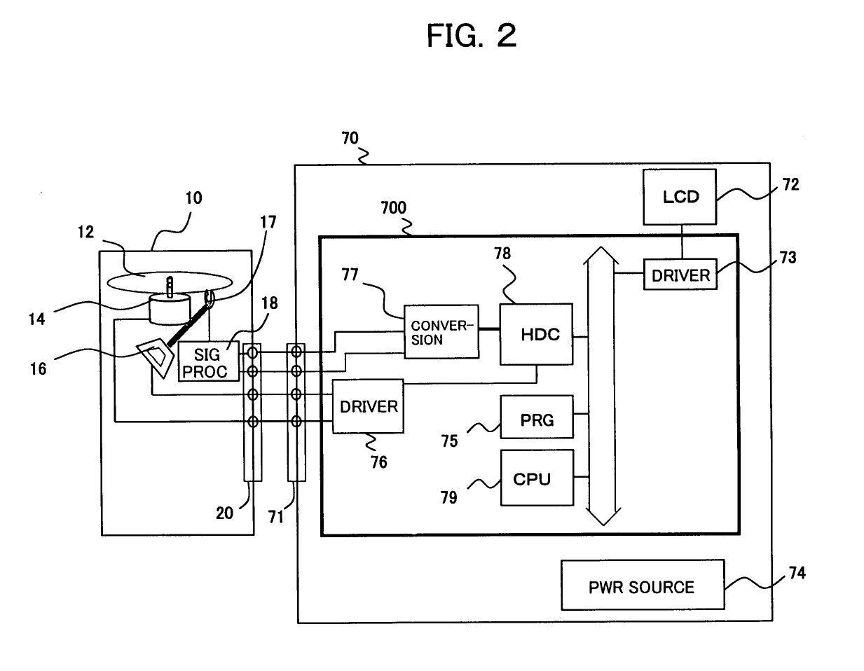

FIG. 2 is a functional block diagram of the inspection apparatus 70 according to an embodiment of the present invention. As shown in FIG. 2, the inspection apparatus 70 has for example an inspection unit 700.

Inspection Unit 700

The inspection unit 700 inspects the magnetic conversion characteristics of the magnetic disk 12 before assembling the HDA 10 into the magnetic disk device 1. Further, the inspection unit 700 assembles the HDA 10 and the processing unit 30 into the magnetic disk device 1 conditional on the magnetic conversion characteristics of the magnetic disk device 12 being found to be proper by that inspection. In more detail, the inspection unit 700 outputs a signal instructing assembly of the HDA 10 and the processing unit 30 into the magnetic disk device 1 to a not illustrated assembly apparatus conditional on the magnetic conversion characteristics of the magnetic disk 12 being found to be proper by that inspection. The assembly apparatus assembles the HDA 10 and the processing unit 30 into the magnetic disk device 1 when that signal is input.

Further, the inspection unit 700 writes an inspection signal having for example a single frequency characteristic into the magnetic disk 12, then reads out the inspection signal from the magnetic disk and inspects the magnetic conversion characteristics on the basis of the read out signal. The inspection signal is an RF signal having a single frequency characteristic of for example about 2 MHz to several tens MHz as the frequency characteristic. This inspection signal is used when inspecting the magnetic conversion characteristics of the magnetic disk 12, that is, whether or not a signal written on the magnetic disk 12, by the head 17 can be read out as a signal having a predetermined intensity by the head 17. As the frequency of this inspection signal, a frequency optimum for inspecting the magnetic conversion characteristics of the magnetic disk 12 to be inspected is set.

Below, an explanation will be given of a preferable example of the inspection unit 700. As shown in FIG. 2, the inspection unit 700 has for example an HDA interface 71, LCD 72, LCD driver 73, power supply circuit 74, memory 75, driver 76, conversion circuit 77, HDC 78, and CPU 79.

The HDA interface 71 is connected to the interface 20 of the HDA 10 and inputs and outputs data with the HDA 10. The LCD 72 displays an image on a screen under the control of the LCD driver 73. The screen is for example an inspection operation screen. The LCD driver 73 controls the display of the LCD 72 on the basis of the control signal from the CPU 79. The power supply circuit 74 supplies power to the components of the inspection apparatus 70.

The memory 75 stores a program PRG for realizing the functions according to an embodiment of the present invention for defining the processing of the CPU 79. The driver 76 outputs, under the control of the HDC 78, control signals to the spindle motor 14 and the VCM 16 of the HDA 19, for example, a control signal for controlling the head position for writing and reading the inspection signal and a control signal for rotating the spindle motor 14.

The conversion circuit 77 outputs for example an inspection signal via the HDA interface 71 to the signal processor 18 of the HDA 10 under the control of the HDC 78. Further, the conversion circuit 77 performs the signal processing of the inspection signal read out from the HDA 10 under the control of the HDC 78 and outputs the same to the HDC 78.

The HDC 78 centrally controls the access to the HDA 10 under the control of the CPU 79. The CPU 79 inspects the magnetic conversion characteristics of the magnetic disk 12 by controlling the drive unit of the HDA 10 before assembling the HDA 10 into the magnetic disk device 1. In more detail, the CPU 79 outputs a control signal for writing an inspection signal on the magnetic disk to for example the HDC 78, outputs a control signal for reading the inspection signal from the magnetic disk 12 to the HDC 78, and inspects the magnetic conversion characteristics on the basis of the read out signal.

Below, the operation according to an embodiment of the present invention will be explained.

Example of Operation

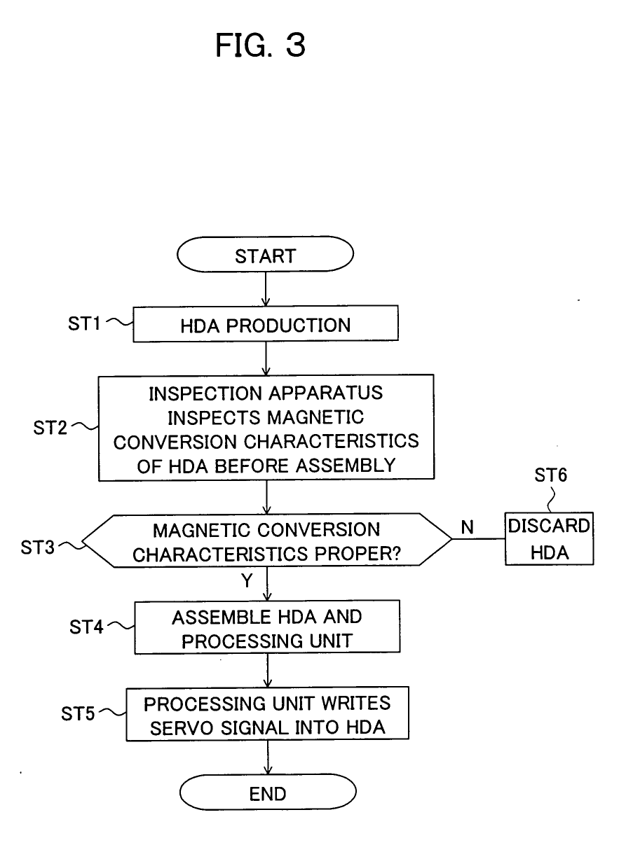

FIG. 3 is a flow chart for explaining the operations of the magnetic disk device and the inspection apparatus shown in FIG. 1 and FIG. 2. Referring to FIG. 3, an explanation will be given of the method for producing the magnetic disk device 1 centering on the operations of the CPU 79 of the inspection apparatus 70 and the CPU 66 of the magnetic disk device 1.

At step ST1, the HDA 10 is produced. In more detail, the HDA 10 is produced by assembling the magnetic disk 12, spindle motor 14, VCM 16, head 17, signal processor 18, etc. into the HDA 10 by for example a not illustrated assembly apparatus. At this time, the servo signal for defining the head position of the head 18 is not written on the magnetic disk 12.

At step ST2, the inspection unit 700 of the inspection apparatus 70 inspects the magnetic conversion characteristics of the magnetic disk 12 before assembling the HDA 10 into the magnetic disk device 1. For example, the inspection is carried out by electrically connecting the HDA interface 71 of the inspection apparatus 70 and the interface 20 of the HDA 10. The detailed operation for inspection of the magnetic conversion characteristics will be explained later.

At step ST3, the inspection unit 700 of the inspection apparatus 70 judges whether or not the magnetic conversion characteristics of the magnetic disk 12 are proper by the inspection. For example, when the magnetic conversion characteristics of the magnetic disk 12 are found to be proper by the inspection, the inspection unit 700 of the inspection apparatus 70 outputs an instruction for assembling the HDA 10 and the processing unit 30 into the magnetic disk device 1 to a not illustrated assembly apparatus.

At step ST4, conditional on the magnetic conversion characteristics being proper, the HDA 10 and the processing unit 30 are assembled into the magnetic disk device 1. In more detail, when an instruction for assembling the HDA 10 and the processing unit 30 into the magnetic disk device 1 is input from the inspection apparatus 70, a not illustrated assembly apparatus, assembles the HDA 10 and the processing unit 30 into the magnetic disk device 1 and electrically connects the interface 20 of the HDA 10 and the HDA interface 31.

At step ST5, the assembled processing unit 30 controls the drive unit such as VCM 16 of the HDA 10 and the signal processor 18 and writes the servo signal to (in) the magnetic disk 12 (self-servo write).

On the other hand, if the CPU 70 of the inspection unit 700 judges at step ST3 that the magnetic conversion characteristics are not proper, the HDA 10 is discarded (ST6). In more detail, when the CPU 79 of the inspection unit 700 judges that the magnetic conversion characteristics are not proper, it outputs a signal indicating that to the assembly apparatus. When that signal is input, the assembly apparatus discards the HDA 10.

Inspection of Magnetic Conversion Characteristic

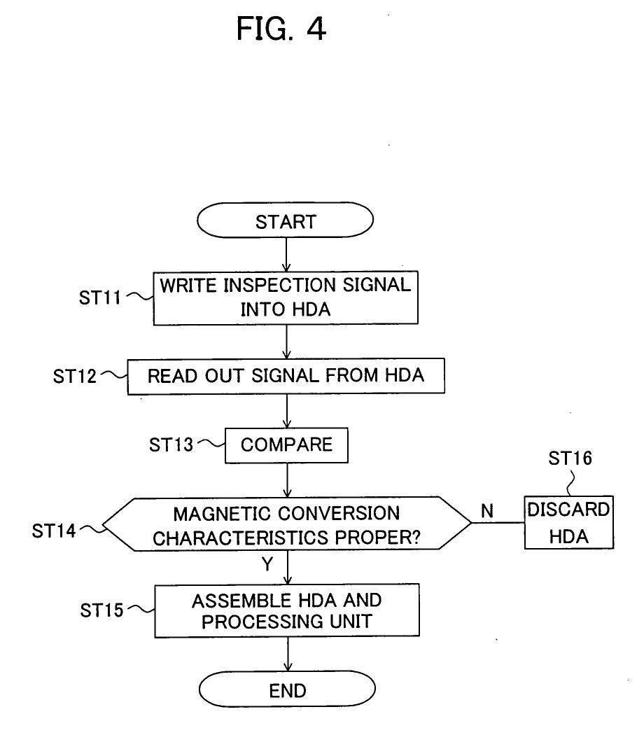

FIG. 4 is a flow chart for explaining a specific example of the operations of the inspection apparatus 70 and the processing unit 30 shown in FIG. 3. A more detailed explanation will be given of the operation according to the inspection of the magnetic conversion characteristics of steps ST2 to ST4 shown in FIG. 3 by referring to FIG. 4.

At step ST11, the inspection unit 700 of the inspection apparatus 70 writes the inspection signal to the HDA 10 before assembly. In more detail, the CPU 79 of the inspection unit 700 outputs a control signal for writing the inspection signal to the HDC 78. The HDC 78 receives the control signal and controls the driver 76 and the conversion circuit 77 and controls the drive unit of the HDA 10 to write the inspection signal in (on) the magnetic disk 12.

At step ST12, the inspection unit 700 then reads out the inspection signal from the HDA 10. In more detail, the CPU 79 of the inspection unit 700 outputs a control signal for reading the inspection signal from the HDA 10 in (to) the HDC 78. The HDC 78 receives the control signal and controls the driver 76 and the conversion circuit 77 and controls the drive unit of the HDA 10 to read out the inspection signal and outputs the same to the CPU 79.

At step ST13, the CPU 79 judges whether or not the magnetic conversion characteristics of the magnetic disk 12 are proper on the basis of for example the written inspection signal and the read out inspection signal. In more detail, where an inspection signal having a single frequency characteristic is written on the magnetic disk 12 as the inspection signal, the CPU 79 judges whether or not the magnetic conversion characteristics of the magnetic disk 12 are proper by comparing the level of the inspection signal read out from the magnetic disk 12 and a predetermined value.

At step ST15, when judging that the magnetic conversion characteristics are proper, the HDA 10 and the processing unit 30 are assembled into the magnetic disk device 1. In more detail, for example the CPU 79 outputs a signal instructing assembly of the HDA 10 and the processing unit 30 into the magnetic disk device 1. When the signal instructing assembly is input, a not illustrated assembly apparatus assembles the HDA 10 and the processing unit 30 into the magnetic disk device 1 and electrically connects the interface 20 of the HDA 10 and the HDA interface 31.

On the other hand, when judging at step ST14 that the magnetic conversion characteristics are not suitable, the HDA 10 is discarded. In more detail, when judging that the magnetic conversion characteristics are not proper, the CPU 79 outputs a signal indicating that to the assembly apparatus. When that signal is input, the assembly apparatus discards the HDA 10 (ST16).

As explained above, before assembling the HDA 10 into the magnetic disk device 1, the magnetic conversion characteristics of the magnetic disk 12 are inspected. Conditional on that inspection showing that the magnetic conversion characteristics of the magnetic disk 12 are proper, the HDA 12 and the processing unit 30 are assembled into the magnetic disk device 1 and the assembled processing unit 30 controls the drive unit of the HDA 10 to write the servo signal on the magnetic disk 12, so it is possible to reduce the ratio of the magnetic disk devices into which defective magnetic disks are assembled. Further, since the ratio of the magnetic disk devices 1 in which defective magnetic disks are assembled becomes smaller after the assembly, it is possible to reduce the wasteful cost in comparison with the case where defects of the magnetic disks are discovered after assembly and the entire magnetic disk devices are discarded.

In more detail, before assembling the HDA 10, if the magnetic conversion characteristics of the magnetic disk 12 of the HDA 10 are found to not be proper, for example if the magnetic conversion characteristics are smaller than predetermined values, the HDA 10 is discarded at that stage. Therefore, the entire magnetic disk device 1 after assembly will not be discarded.

Further, by inspecting the magnetic conversion characteristics by the simple inspection of writing an inspection signal having a single frequency characteristic on the magnetic disk 12 of the HDA 10 as an inspection signal, reading out that signal, and judging whether or not the signal level thereof is a predetermined value or more, it is possible to inspect for problems in the magnetic disk 12 of the HDA 10 in a shorter time in comparison with the case of for example writing a servo signal on the entire magnetic disk 12 before assembly and reading out that signal for inspection.

Further, it is also possible for example for the CPU 79 of the inspection unit 700 to write an inspection signal having a predetermined modulation pattern on the magnetic disk 12 as the inspection signal, then read out the inspection signal from the magnetic disk and inspect the magnetic conversion characteristics on the basis of the read out signal. The predetermined modulation pattern may be for example an inspection signal having a plurality of frequency characteristics or may be an inspection signal having a modulation pattern simpler than that of the servo signal as well. By doing this, it is possible to inspect the more detailed magnetic conversion characteristics of the magnetic disk 12.

Further, as the inspection signal, the CPU 79 of the inspection unit 700 may write an inspection signal into only part of the tracks of the magnetic disk 12, then read out the inspection signal from part of the tracks and inspect the magnetic conversion characteristics on the basis of the read out signal. For example, it is possible to inspect any of the outer tracks, middle tracks, or inner tracks of the magnetic disk 12 or combinations of these tracks, desired tracks, etc. By doing this, it is possible to inspect the magnetic conversion characteristics of the magnetic disk 12 in a shorter time in comparison with the case for example of writing the inspection signal into all tracks of the magnetic disk 12, reading out that signal, and inspecting the magnetic conversion characteristics of the magnetic disk 12.

First, an explanation will be given of correspondence between the configuration of the embodiment and the configuration of the present invention as expressed in the claims. A magnetic disk device 1 shown in FIG. 1 corresponds to the magnetic disk device according to the present invention. An inspection apparatus 70 shown in FIG. 2 corresponds to the inspection apparatus according to the present invention, and an inspection unit 700 corresponds to the inspecting means according to the present invention. A magnetic disk 12 shown in FIG. 1 corresponds to the magnetic disk according to the present invention, and a spindle motor 14, a voice control motor (VCM) 16, and a head 17 correspond to the drive unit according to the present invention.

Step ST2 shown in FIG. 3 corresponds to a first step of the first aspect of the invention, and steps ST3 to ST6 correspond to a second step of the first aspect of the invention. Further, step ST2 shown in FIG. 3 corresponds to the first step of the third aspect of the invention, and step ST3 corresponds to the second step of the third aspect of the invention.

It should be understood by those skilled in the art that various modifications, combinations, sub-combinations, and alterations may occur depending on design requirements and other factors insofar as they are within the scope of the appended claims or the equivalents thereof.

For example, the inspection unit 700 of the inspection apparatus 70 need not have the above-mentioned configuration. For example, it may have components able to perform the processing according to the above embodiment of the present invention. For example, it may be provided with an oscillation device for writing an inspection signal having a single frequency characteristic or desired modulation pattern on the magnetic disk 12, a measurement device for measuring the level of the read RF signal for the inspection signal read out from the magnetic disk 12, and a control unit for controlling them to realize the functions of the embodiment of the present invention.

Further, in the above embodiment, the HDA 10 inspected by the inspection apparatus 70 was configured by a magnetic disk 12 and a drive unit, but the invention is not limited to this. For example, a control circuit for performing the function of the processing unit 30 may be provided in the HDA 10 as well. In that case as well, the inspection apparatus 70 realizes the functions according to the above embodiment of the present invention via that processing circuit.

What we claim is:

1. A method of producing a magnetic disk device having a disk drive means including a magnetic disk and a drive unit for driving the magnetic disk and a control means for controlling said drive unit to control access to said magnetic disk and write a servo signal in said magnetic disk, said method comprising:
a first step of inspecting magnetic conversion characteristics of said drive unit; and
a second step of connecting said disk drive means and said control means when it is judged by the inspection of said first step that the magnetic conversion characteristics of said drive unit are proper.

2. A method of producing a magnetic disk device as set forth in claim 1, further comprising a third step of controlling said drive unit by said control means after the second step to write the servo signal on said magnetic disk.

3. A method of producing a magnetic disk device as set forth in claim 1, wherein:
said first step includes
a step of writing an inspection signal in said magnetic disk by said drive unit,
a step of reading the inspection signal from said magnetic disk, and
a step of comparing said inspection signal written on said magnetic disk and the inspection signal read out from the magnetic disk, and
said second step includes a step of connecting said disk drive means and said control means when it is judged as a result of the comparison of the inspection signals that the magnetic conversion characteristics of said drive unit are proper.

4. A method of producing a magnetic disk device as set forth in claim 3, wherein said inspection signal comprises an inspection signal having a single frequency characteristic.

5. A method of producing a magnetic disk device as set forth in claim 3, wherein said inspection signal comprises an inspection signal having a predetermined modulation pattern.

6. A method of producing a magnetic disk device as set forth in claim 3, wherein in the step of writing said inspection signal, the inspection signal is written into part of the tracks of said magnetic disk.

7. An inspection apparatus for inspecting a magnetic disk device having a disk drive means including a magnetic disk and a drive unit for driving the magnetic disk and a control means for controlling said drive unit to control access to said magnetic disk and write a servo signal on said magnetic disk, said apparatus comprising:
an inspecting means for inspecting the magnetic conversion characteristics of said drive unit before connecting said disk drive means and said control means.

8. An inspection apparatus as set forth in claim 7, wherein said inspecting means outputs a control signal for connecting said disk drive means and said control means when it is judged by said inspecting means that the magnetic conversion characteristics of said drive unit are proper.

9. An inspection apparatus as set forth in claim 7, wherein said inspecting means writes an inspection signal in said magnetic disk by said drive unit, reads out the inspection signal from the magnetic disk, and compares the inspection signal written on the magnetic disk and the inspection signal read out from the magnetic disk.

10. An inspection apparatus as set forth in claim 9, wherein said inspection signal comprises an inspection signal having a single frequency characteristic.

11. An inspection apparatus as set forth in claim 9, wherein said inspection signal comprises an inspection signal having a predetermined modulation pattern.

12. An inspection apparatus as set forth in claim 9, wherein said inspecting means writes said inspection signal by writing the inspection signal into part of the tracks of said magnetic disk.
